(19) United States
(12) Patent Application Publication
(10) Pub. No.: US 2024/0357736 A1
(43) Pub. Date: Oct. 24, 2024

(54) WIRING SUBSTRATE FOR ELECTRONIC CONTROL DEVICE, AND METHOD FOR MANUFACTURING SAME

(71) Applicant: HITACHI ASTEMO, LTD., Hitachinaka-shi, Ibaraki (JP)

(72) Inventors: Takanori SEKIGUCHI, Hitachinaka-shi, Ibaraki (JP); Takayuki DEGUCHI, Hitachinaka-shi, Ibaraki (JP)

(73) Assignee: HITACHI ASTEMO, LTD., Hitachinaka-shi, Ibaraki (JP)

(21) Appl. No.: 18/684,457

(22) PCT Filed: Aug. 15, 2022
(86) PCT No.: PCT/JP2022/030839

§ 371 Date: Feb. 16, 2024

(30) Foreign Application Priority Data
Sep. 13, 2021 (JP) 2021-148484

(51) Int. Cl. H05K 1/02; H05K 1/11; H05K 3/42

(52) U.S. Cl. CPC H05K 1/0268; H05K 1/113; H05K 3/429; H05K 2201/09509; H05K 2201/09572; H05K 2201/09827; H05K 2203/045; H05K 2203/1121

(57) ABSTRACT

An electronic component is mounted on a surface layer of a multilayer substrate constituting a wiring substrate, and a signal wire of the surface layer is electrically connected to the electronic component. A conductor pad for contact with an inspection probe is composed of a via and a solder filled in an internal opening portion thereof. The via has a laser-processed taper-shaped hole with a metal-plated inner peripheral surface and connects the inter-layer connection between the signal wire of the surface layer and a signal wire of the inner layer. The solder is filled in the opening portion of the via by filling, heating and melting solder material therein. Since the peripheral edge portion is solidified first at the time of the cooling and the solidification, the middle part is recessed compared to the peripheral edge portion. This ensures a reliable contact of the inspection probe.

### TECHNICAL FIELD

The present invention relates to a wiring substrate for an electronic control device, and particularly to a wiring substrate provided with a conductor pad for contact with an inspection probe.

### BACKGROUND TECHNOLOGY

A wiring substrate manufactured through a forming process of a multilayer substrate having a desired circuit and a mounting process of components is individually inspected by using an inspection device such as an ICT (in-circuit tester), after the completion. Therefore, in general, a land portion, namely, a check land with which the distal end of an inspection probe is brought into contact at the time of the inspection is formed at part of the circuit.

A patent document 1 discloses a wiring substrate formed in such a way that, after filling resin into the inside of a blind hole having a conductive pattern on the inner periphery thereof, a check land is formed on the substrate surface so as to cover the blind hole and the conductive pattern of the blind hole is connected to a circuit pattern of an inner layer.

However, according to the above configuration, a special process in which, after the blind hole is buried with resin, the check land is formed thereon is required, and processes become complicated and manufacturing costs become high.

In addition, the check land made of, for example, copper foil is exposed, and an inspection probe directly comes in contact with the exposed part, the check land is easily corroded, or the surface of the check land is easily damaged due to the contact with the inspection probe.

### PRIOR ART REFERENCE

### Patent Document

Patent Document 1: Japanese Patent Application Publication No. 2000-133950

### SUMMARY OF THE INVENTION

A wiring substrate for an electronic control device includes: an electronic component mounted on a multilayer substrate; a signal wire of a surface layer or an inner layer of the multilayer substrate, the signal wire being electrically connected to the electronic component; and a conductor pad for contact with an inspection probe, the conductor pad being provided to the signal wire and exposed on a surface of the multilayer substrate, wherein the conductor pad is composed of: a via provided to the multilayer substrate along a lamination direction of the multilayer substrate and connected to the signal wire; and a solder filled in an opening portion of the via.

In addition, A method for manufacturing a wiring substrate for an electronic control device includes: forming a multilayer substrate provided with a signal wire; forming a via along a lamination direction of the multilayer substrate so as to be electrically connected to a signal wire of a surface layer or an inner layer of the multilayer substrate; disposing a solder material in an opening portion of the via; and heating and cooling the solder material.

According to the present invention, since the inspection probe comes in contact with the surface of the solder, problems such as the corrosion of the conductor pad or wear due to contact with the inspection probe can be suppressed. In addition, solder is simply filled in the via, and manufacturing process becomes simple.

### BRIEF DESCRIPTION OF THE DRAWINGS

FIG. 1 is a plane view of a wiring substrate in one embodiment.

FIG. 2 is a sectional view taken along an A-A line of FIG. 1.

FIG. 3 is an illustrative view showing the relation between the shape of a solder and an inspection probe.

FIG. 4 is a sectional view showing a second embodiment in which a conductor pad is provided in the middle of a signal wire of an inner layer.

FIG. 5 is a plane view showing a third embodiment in which signal wires and conductor pads are symmetrically arranged.

### MODE FOR IMPLEMENTING THE INVENTION

In the following, one embodiment of the present invention will be explained in detail based on the drawings.

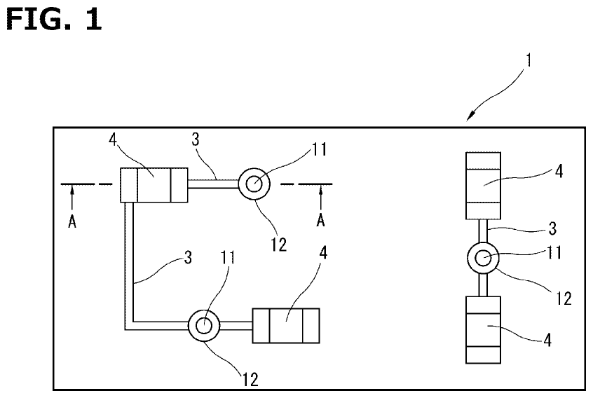

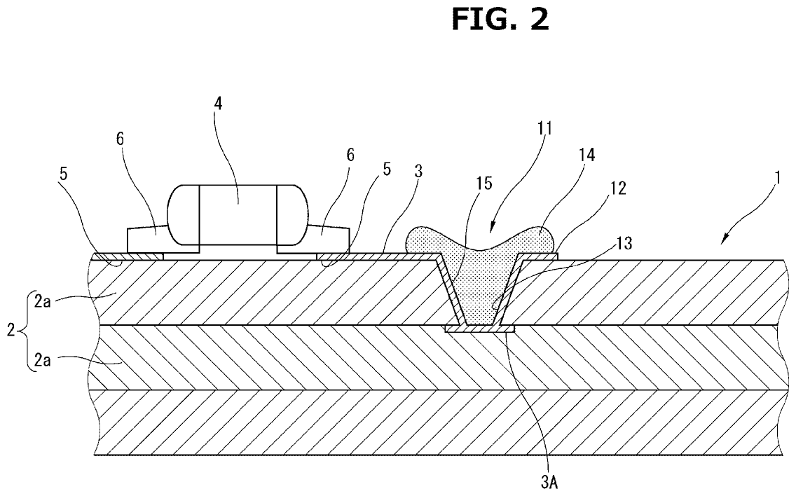

FIG. 1 is a plane view showing part of a wiring substrate 1 as one embodiment of the present invention, and FIG. 2 is a sectional view taken along an A-A line of FIG. 1. The wiring substrate 1 is a multilayer printed wiring substrate in which a multilayer substrate 2 formed by laminating a plurality of insulation material layers 2a with metal foil layers is used, and the metal foil layers positioned on the respective surface layer and inner layer are each formed with a predetermined circuit pattern by using a technique such as etching. In FIG. 1, there is shown a few signal wires formed on the surface layer. In addition, as shown in FIGS. 1 and 2, electronic components 4 are mounted on the multilayer substrate 2, and the signal wires 3 are connected to the electronic components 4. As shown in FIG. 2, each of the electronic components 4 is soldered to a rectangular land portion 5 formed as part of a metal foil layer together with a corresponding signal wire 3 via a solder 6 formed by soldering such as reflow soldering.

As shown in FIG. 1, a conductor pad 11 for contact with an inspection probe is provided to each of the signal wires 3. The conductor pad 11 has a circular shape in a plane view (drawing viewed from a direction orthogonal to the surface) of the wiring substrate 1.

As shown in FIG. 2, the conductor pad 11 is composed of a via 13 provided along the lamination direction of the multilayer substrate 2 in the center of a circular land portion 12 which is formed as part of a metal foil layer together with a signal wire 3, and a solder 14 filled in the opening portion of the via 13. The via 13 is one formed in such a way that, by performing hole processing with, for example, laser, metal plating (for example, copper plating) is applied to the inner peripheral surface of the hole after washing, and, in this embodiment, it is configured as a so-called blind via for distal end sealing which penetrates through only an insulation material layer 2a of a first layer. In addition, by performing the hole processing with laser, the hole is formed in a taper shape in which the surface side of the wiring substrate 1 (surface on the side on which the electronic component 4 is mounted) has a relatively large diameter. A plating layer 15 provided on the inner peripheral surface of the hole is formed continuously to the land portion 12 on the surface of the multilayer substrate 2, so as to be electrically connected therebetween. In addition, as shown in FIG. 2, a signal wire 3A is formed at the metal foil layer of the inner layer which is along the under surface of the insulation material layer 2a of the first layer, and an end portion of the signal wire 3A of the inner layer is connected to the plating layer 15 in the distal end portion of the via 13. In addition, the circular land portion 12 of the surface layer is a substantially annular shape by performing the hole processing to the center.

The solder 14 is filled in the opening portion on the surface side of the wiring substrate 1 of the tapered via 13 which is provided with the plating layer 15. That is, as shown in FIG. 2, the solder 14 is filled in the whole of the opening portion of the inner side of the via 13 having a cup shape. In addition, the solder 14 covers the peripheral edge of the opening portion of the via 13 and part of the land portion 12. The solder 14 is one formed in such a way that, after metal plating is applied to a hole which becomes the via 13, for example, paste-like solder material is filled in the opening potion of the via 13, is melted by being heated with a preferable heating means, and is cooled to be solidified.

Here, when the melted solder material is solidified by the cooling, the temperature of the outer peripheral portion which comes in contact with the plating layer 15 is lowered first, and then the center part is solidified later. Then, the volume of the solder material decreases as the temperature of the melted solder is lowered. Consequently, in a state of being solidified in the end, as shown in FIG. 2, the solder 14 has a shape in which the middle part thereof is recessed as compared to the peripheral edge portion. The peripheral edge portion of the solder 14 having a circular shape in a plane view is superimposed on the surface of the land portion 12 as mentioned above and is therefore located at a position higher the surface position of the land portion 12. The middle part of the solder 14 is recessed so as to be located at a position lower than that of the peripheral edge portion.

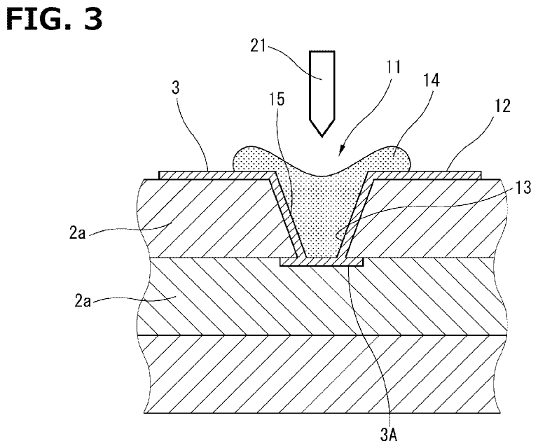

FIG. 3 is an illustrative view showing the relation between the shape of the solder 14 in the conductor pad 11 and the inspection probe 21. In an inspection process using an inspection device such as an ICT (in-circuit tester), the inspection probe 21 having a sharp needle-like distal end is abutted against the conductor pad 11 in the vertical direction (lamination direction) of the wiring substrate 1, and the electrical connection for the inspection is carried out. At this time, the distal end of the inspection probe 21 comes in contact with the recessed middle part of the solder 14. Consequently, a steady contact state can be obtained and the inspection probe 21 is guided to the middle part of the solder 14 even if a slight error in position is present, and other signal wire 3 and the like can be suppressed from being damaged due to the displacement of the inspection probe 21 from the conductor pad 11.

In addition, since the inspection probe 21 comes in contact with the solder 14 which covers the plating layer 15 of the via 13 and the land portion 12 without directly coming in contact with them, the damage and wear of the plating layer 15 and the land portion 12 do not occur. Further, the plating layer 15 and the land portion 12 are not exposed to the outside, and they can be suppressed from the occurrence of the oxidation, corrosion and the like.

In addition, in the present embodiment, the via 13 which becomes the conductor pad 11 has a function as a general via for an inter-layer connection between the signal wire 3 of the surface layer and the signal wire 3A of the inner layer. That is, the via 13 for the inter-layer connection has a configuration which serves as the conductor pad 11, and the conductor pad 11 does not occupy an excessive area in the wiring substrate 1. Therefore, it is an advantage of increasing mounting density of components in the wiring substrate 1.

In addition, the conductor pad 11 in the above-mentioned embodiment is not formed to be a so-called stub wiring, and trouble such as sympathetic vibration and impedance mismatching due to the forming of the stub wiring do not occur.

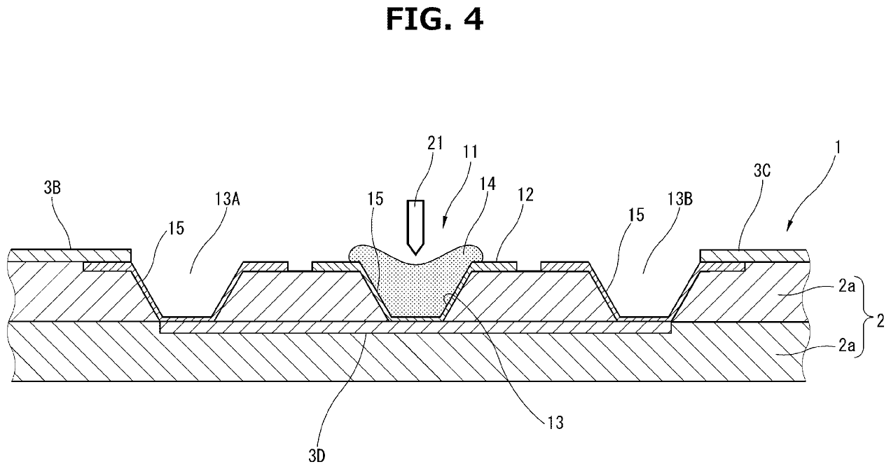

Next, FIG. 4 shows a sectional view of the wiring substrate 1 in a second embodiment. In the second embodiment, a signal wire 3B and signal wire 3C of the surface layer are connected to each other via a signal wire 3D of the inner layer. An end portion of the signal wire 3B and one end portion of a signal wire 3D are connected to each other by a via 13A for inter-layer connection, and the other end portion of the signal wire 3D and an end portion of the signal wire 3C are connected to each other by the via 13B for inter-layer connection. With this, the signal wires 3B, 3D and 3C form a one continuous signal wire. The configuration of each of the vias 13A and 13B is the same as that of the via 13 which serves as the conductor pad 11, except that the solder 14 is not provided. That is, plating is applied to the inner peripheral surface of a hole of each of them which is formed by, for example, laser.

A conductor pad 11 for contact with an inspection probe is provided to the middle part of the signal wire 3D which passes at the inner layer. The conductor pad 11 itself is the same as that of the embodiment mentioned above and is composed of a via 13 provided along the lamination direction of the multilayer substrate 2 and a solder 14 filled in the opening portion of the via 13. The solder 14 has a shape in which the middle part is recessed. However, a signal wire is not connected to the conductor pad 11 on the surface layer. That is, the conductor pad 11 is provided independently from the signal wires 3B and 3C and the like of the surface layer.

In such a configuration, since a signal wire that is an inspection object is not exposed around the conductor pad 11, disconnection caused by contact of the inspection probe 21 with a signal wire accidentally can be certainly suppressed.

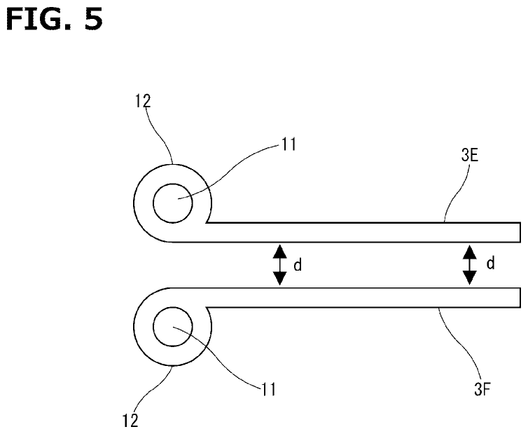

Next, in FIG. 5, there is shown a third embodiment in which a conductor pad 11 is provided to one end portion of a pair of each of signal wires 3E and 3F for differential signal. In this embodiment, the pair of the signal wires 3E and 3F are arranged so as to be symmetrical to each other and are provided parallel to each other such that a distance “d” therebetween is constant in every part. Then, circular land portions 12, which are displaced to the outside, and conductor pads 11 are disposed to the respective signal wires 3E and 3F such that the same distance “d” is also kept at the end portions provided with the conductor pads 11. The configuration of each of the conductor pads 11 is basically the same as that of the embodiments mentioned above.

As the above, although one embodiment of the preset invention has been explained, the present invention is not limited to the above embodiments, and various changes can be made to the embodiments. For example, although, in the above embodiments, the via 13 which serves as the conductor pad 11 is formed in a non-through blind via, it can be formed in a shape in which a hole penetrates through the entire multilayer substrate 2. In addition, the number of layers of the multilayer substrate 2, material and the like are arbitrary.

1. A wiring substrate for an electronic control device, comprising:
an electronic component mounted on a multilayer substrate;
a signal wire of a surface layer or an inner layer of the multilayer substrate, the signal wire being electrically connected to the electronic component; and
a conductor pad for contact with an inspection probe, the conductor pad being provided to the signal wire and exposed on a surface of the multilayer substrate,
wherein the conductor pad is composed of:
a via provided to the multilayer substrate along a lamination direction of the multilayer substrate and connected to the signal wire; and
a solder filled in an opening portion of the via.

2. The wiring substrate for the electronic control device according to claim 1, wherein the solder filled in the opening portion is formed in a shape in which a middle part is recessed compared to a peripheral edge portion of the solder.

3. The wiring substrate for the electronic control device according to claim 1, wherein the via is connected to a signal wire provided to the inner layer of the multilayer substrate and is provided independently from another signal wire on the surface of the multilayer substrate.

4. The wiring substrate for the electronic control device according to claim 1, wherein the via connects a signal wire on the surface layer of the multilayer substrate with a signal wire on the inner layer of the multilayer substrate in the lamination direction of the multilayer substrate.

5. The wiring substrate for the electronic control device according to claim 1, wherein the via is a blind via.

6. The wiring substrate for the electronic control device according to claim 1, wherein the via has a taper shape in which an opening portion side in which the solder is filled has a relatively large diameter.

7. A method for manufacturing a wiring substrate for an electronic control device, comprising:
forming a multilayer substrate provided with a signal wire;
forming a via along a lamination direction of the multilayer substrate so as to be electrically connected to a signal wire of a surface layer or an inner layer of the multilayer substrate;
disposing a solder material in an opening portion of the via; and
heating and cooling the solder material.
